(19) United States
(12) Patent Application Publication
(10) Pub. No.: US 2025/0254444 A1
(43) Pub. Date: Aug. 7, 2025

(54) IMAGE SENSING DEVICE

(71) Applicant: SK hynix Inc., Icheon-si (KR)

(72) Inventor: Seung Hoon SA, Icheon-si (KR)

(21) Appl. No.: 18/934,098

(22) Filed: Oct. 31, 2024

(30) Foreign Application Priority Data
Feb. 5, 2024 (KR) 10-2024-0017703

(51) Int. Cl. H04N 25/77

(52) U.S. Cl. CPC H04N 25/77

(57) ABSTRACT

An image sensing device is disclosed to disclose first to fourth pixels arranged in a (2×2) matrix structure in which the first pixel and the second pixel are adjacent to each other in a first direction and the first pixel and the third pixel are adjacent to each other in a second direction, and the first to fourth pixels configured to generating photocharges corresponding to incident light and configured to share at least one element; and a body bias region disposed at a location defined by a first region between a boundary of the first pixel and a boundary of the second pixel and a second region between the boundary of the first pixel and a boundary of the third pixel, and the body bias region configured to receive a bias voltage as an input.

### CROSS-REFERENCE TO RELATED APPLICATION

This patent document claims the priority and benefits of Korean patent application No. 10-2024-0017703, filed on Feb. 5, 2024, the disclosure of which is incorporated herein by reference in its entirety as part of the disclosure of this patent document.

### TECHNICAL FIELD

The technology and embodiments disclosed in this patent document generally relate to an image sensing device, and more particularly to an image sensing device including a source follower transistor and a body bias region.

### BACKGROUND

An image sensing device is a device for capturing at least one image using semiconductor characteristics that react to light incident thereon to produce an image. In recent times, with the increasing development of information technology (IT) industries and related technologies, the demand for high-quality and high-performance image sensing devices has been rapidly increasing in various electronic devices, for example, smartphones, digital cameras, etc.

Image sensing devices may be broadly classified into CCD (Charge Coupled Device)-based image sensing devices and CMOS (Complementary Metal Oxide Semiconductor)-based image sensing devices. CMOS image sensing devices have been intensively researched and rapidly come into widespread use.

### SUMMARY

Various embodiments of the disclosed technology relate to an image sensing device with a structure that secures a larger area for a gate region of a source follower transistor to reduce the amount of noise and effectively applies a bias voltage to a substrate in which one or more pixels are formed.

In accordance with an embodiment of the disclosed technology, first to fourth pixels arranged in a (2×2) matrix structure in which the first pixel and the second pixel are adjacent to each other in a first direction and the first pixel and the third pixel are adjacent to each other in a second direction, and the first to fourth pixels configured to generating photocharges corresponding to incident light and configured to share at least one element; and a body bias region disposed at a location defined by a first region between a boundary of the first pixel and a boundary of the second pixel and a second region between the boundary of the first pixel and a boundary of the third pixel, and the body bias region configured to receive a bias voltage as an input.

In some implementations, the image sensing device may further include: a first pixel isolation structure configured to surround outer walls of the (2×2) matrix structure; a second pixel isolation structure configured to contact the first pixel isolation structure, disposed between the first pixel and the second pixel, and spaced apart from the body bias region; and a third pixel isolation structure configured to contact the first pixel isolation structure, disposed between the first pixel and the third pixel, and spaced apart from the body bias region.

In some implementations, the first pixel may be configured to have a first photoelectric conversion element that generates photocharges in response to incident light; the second pixel may be configured to have a second photoelectric conversion element that generates photocharges in response to the incident light; the third pixel may be configured to have a third photoelectric conversion element that generates photocharges in response to the incident light; and the fourth pixel may be configured to have a fourth photoelectric conversion element that generates photocharges in response to the incident light.

In some implementations, the at least one element may include: a shared floating diffusion region configured to store photocharges generated by each of the first to fourth photoelectric conversion elements; and a shared source follower transistor including a gate that is configured to receive a voltage corresponding to the photocharges stored in the shared floating diffusion region, and is structured to overlap the first pixel.

In some implementations, the gate of the shared source follower transistor may further overlap the second pixel.

In some implementations, the gate of the shared source follower transistor may be spaced apart from the body bias region, and a shortest distance between the body bias region and the gate of the shared source follower transistor may be shorter than a shortest distance between the body bias region and a center of the first pixel.

In some implementations, the at least one element may further include a shared reset transistor configured to reset the shared floating diffusion region and including a gate that is structured to overlap the second pixel.

In some implementations, each of the gate of the shared source follower transistor and the gate of the shared reset transistor may include an oxide layer, wherein the oxide layer of the gate of the shared source follower transistor is thinner than the oxide layer of the gate of the shared reset transistor.

In some implementations, the at least one element may further include a shared selection transistor including a gate which is structured to overlap the second pixel, a first terminal and a second terminal, wherein the first terminal is connected to the shared source follower transistor, and the shared source follower transistor is configured to output a pixel signal of each of the first to fourth pixels through the second terminal.

In some implementations, each of a gate of the shared source follower transistor and a gate of the shared selection transistor may include an oxide layer, wherein the oxide layer of the gate of the shared source follower transistor is thinner than the oxide layer of the gate of the shared selection transistor.

In some implementations, a source region of the shared source follower transistor is disposed in one direction with respect to the gate of the shared source follower transistor; and a drain region of the shared source follower transistor is disposed in another direction with respect to the gate of the shared source follower transistor that is different from the one direction.

In some implementations, the at least one element may further include a shared dual conversion gain (DCG) transistor configured to vary capacitance of the shared floating diffusion region, wherein a gate of the shared DCG transistor is formed to overlap the second pixel.

In accordance with another embodiment of the disclosed technology, an image sensing device may include: a semiconductor substrate configured to have a first surface upon which light is incident and a second surface opposite to the first surface; first to fourth photoelectric conversion elements supported by the semiconductor substrate and arranged to be spaced apart from each other in a (2×2) matrix structure, each photoelectric conversion element configured to generate photocharges in response to the incident light; a first pixel isolation structure located between the first and second photoelectric conversion elements and recessed from the second surface into the semiconductor substrate, and configured to extend along a first direction; a second pixel isolation structure located between the first and third photoelectric conversion elements and recessed from the second surface into the semiconductor substrate, and configured to extend along a second direction perpendicular to the first direction; and a body bias region disposed in an intersection region where an extension line of the first pixel isolation structure in the first direction and an extension line of the second pixel isolation structure in the second direction cross each other, the body bias region configured to receive a bias voltage.

In some implementations, the image sensing device may further include a shared floating diffusion region supported by the semiconductor substrate, and configured to be coupled to receive and store photocharges generated by each of the first to fourth photoelectric conversion elements; and a first shared source follower transistor supported by the semiconductor substrate and including a gate structured to overlap the first photoelectric conversion element and configured to receive a voltage corresponding to the photocharges stored in the shared floating diffusion region.

In some implementations, the image sensing device may further include: the first pixel isolation structure extends in the first direction so as to overlap a space between the first shared source follower transistor and the second shared source follower transistor.

In some implementations, the image sensing device may further include: a shared reset transistor configured to reset the shared floating diffusion region; and a shared selection transistor configured to output a pixel signal using electrical signals output from the first and second shared source follower transistors, wherein a gate of the shared reset transistor is configured to overlap the third photoelectric conversion element, and a gate of the shared selection transistor is configured to overlap the fourth photoelectric conversion element.

In some implementations, each of the gate of the first shared source follower transistor and the gate of the shared reset transistor may include an oxide layer, wherein the oxide layer of the gate of the first shared source follower transistor is thinner than the oxide layer of the gate of the shared reset transistor.

In some implementations, each of the gate of the first shared source follower transistor and the gate of the shared selection transistor may include an oxide layer, wherein the oxide layer of the gate of the first shared source follower transistor is thinner than the oxide layer of the gate of the shared selection transistor.

In some implementations, the semiconductor substrate may have a first conductivity type, each of the first to fourth photoelectric conversion elements may have a second conductivity type, and the body bias region may have the first conductivity type, wherein a doping concentration of the first conductivity type in the body bias region is higher than a doping concentration of the first conductivity type in the semiconductor substrate.

In accordance with another embodiment of the disclosed technology, an image sensing device may include: first to fourth pixels arranged in a (2×2) matrix structure, each of the first to fourth pixels including a photoelectric conversion element configured to generate photocharges in response to incident light; a body bias region disposed at a center of the (2×2) matrix structure and configured to receive a bias voltage as an input of the first to fourth pixels; a shared source follower transistor including a gate configured to overlap the first pixel and the second pixel, the gate of the shared source follower transistor disposed to be spaced apart from the body bias region, and configured to receive a voltage corresponding to a shared floating diffusion region storing the photocharges; and a first pixel isolation structure disposed between the first pixel and the second pixel and configured to extend in a first direction, and spaced apart in the first direction from the body bias region and the gate of the shared source follower transistor.

In some implementations, the image sensing device may further include a second pixel isolation structure disposed between the first pixel and the third pixel and configured to extend in a second direction perpendicular to the first direction and spaced apart from the body bias region in the second direction; and a shared reset transistor including a gate configured to overlap the third pixel and spaced apart from the body bias region, and wherein the gate of the shared reset transistor is configured to reset the shared floating diffusion region.

In some implementations, each of the gate of the shared source follower transistor and the gate of the shared reset transistor includes an oxide layer, wherein the oxide layer of the gate of the shared source follower transistor is thinner than the oxide layer of the gate of the shared reset transistor.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example of a pixel array shown in FIG. 1 based on some implementations of the disclosed technology.

FIG. 3 is a circuit diagram illustrating an example of a pixel group shown in FIG. 2 based on some implementations of the disclosed technology.

FIG. 4 is a plan view illustrating an example of the pixel group shown in FIG. 2 based on some implementations of the disclosed technology.

FIG. 5 is a plan view illustrating an example of another embodiment of the pixel group shown in FIG. 2 based on some implementations of the disclosed technology.

FIG. 6 is a cross-sectional view illustrating an example of the pixel group taken along the line A-A′ of FIG. 4 based on some implementations of the disclosed technology.

FIG. 7 is a cross-sectional view illustrating an example of the pixel group taken along the line B-B′ of FIG. 4 based on some implementations of the disclosed technology.

FIG. 8 is a cross-sectional view illustrating an example of the pixel group taken along the line C-C′ of FIG. 4 based on some implementations of the disclosed technology.

FIG. 9 is a cross-sectional view illustrating an example of the pixel group taken along the line D-D′ of FIG. 4 based on some implementations of the disclosed technology.

FIG. 10 is a cross-sectional view illustrating an example of the pixel group taken along the line E-E′ of FIG. 5 based on some implementations of the disclosed technology.

### DETAILED DESCRIPTION

This patent document provides embodiments and examples of an image sensing device including a source follower transistor and a body bias region that may be used in configurations to substantially address one or more technical or engineering issues and to mitigate limitations or disadvantages encountered in some image sensing devices in the art. Some embodiments of the disclosed technology relate to an image sensing device with a structure that secures a larger area for a gate region of a source follower transistor to reduce the amount of noise and effectively applies a bias voltage to a substrate in which one or more pixels are formed. The image sensing device based on some implementations of the disclosed technology may be formed with a structure that secures a larger area for a gate region of a source follower transistor to reduce the amount of noise and effectively applies a bias voltage to a substrate in which one or more pixels are formed.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

In describing the components of the embodiments of the disclosed technology, various terms such as first, second, etc., may be used solely for the purpose of differentiating one component from another, but the essence, order and sequence of the components are not limited to these terms. Unless defined otherwise, all terms, including technical and scientific terms, used in the disclosed technology may have the same meaning as commonly understood by a person having ordinary skill in the art to which the disclosed technology pertains. It will be further understood that terms, such as those defined in commonly used dictionaries, may be interpreted as having a meaning that is consistent with their meaning in the context of the related art and the disclosed technology, and should not be interpreted in an idealized or overly formal sense unless expressly so defined herein.

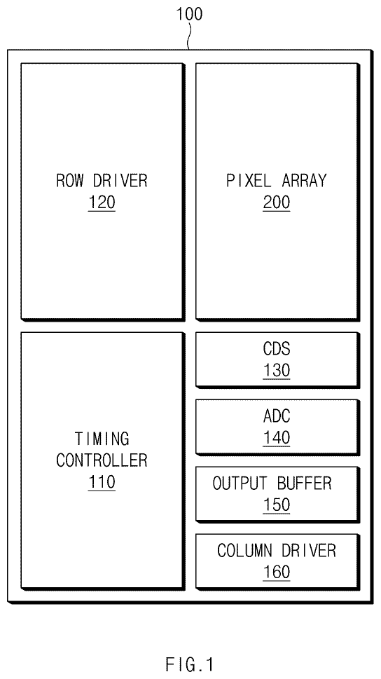

FIG. 1 is a block diagram illustrating an example of an image sensing device 100 based on some implementations of the disclosed technology.

Referring to FIG. 1, the image sensing device 100 based on some implementations of the disclosed technology may include a timing controller 110, a row driver 120, a pixel array 200, a correlated double sampler (CDS) 130, an analog-to-digital converter (ADC) 140, an output buffer 150, and a column driver 160. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The timing controller 110 may provide timing signals and control signals to at least one of the row driver 120, the correlated double sampler (CDS) 130, the ADC 140, the output buffer 150, and the column driver 160.

The row driver 120 may activate the pixel array 200 to perform specific operations on pixels included in a corresponding row based on the timing and control signals received from the timing controller 110.

In some implementations, the row driver 120 may select at least one pixel arranged in at least one row of the pixel array 200, and may provide the selected pixel with a control signal for performing a specific operation. The row driver 120 may generate a row selection signal to select at least one row from among a plurality of rows. When the row driver 120 selects a specific row from among the plurality of rows to perform a specific operation, the row driver 120 may not perform the specific operation on a row adjacent to the selected specific row.

The pixels of the row selected by the row driver 120 may sequentially transfer analog reference signals and image signals to the correlated double sampler (CDS) 130. The reference signal may be an electrical signal provided to the CDS 130 when a floating diffusion region of each pixel is reset to a power-supply voltage VDD. The image signal may be an electrical signal provided to the CDS 130 when photocharges generated by each pixel are accumulated in the floating diffusion region (FD).

The reference signal may be a signal indicating unique pixel noise of each pixel, and the reference signal and the image signal may be collectively referred to as a pixel signal as necessary.

The pixel array 200 may include a plurality of pixels arranged in a plurality of rows and a plurality of columns. The plurality of pixels may be connected to the row driver 120 through a plurality of row lines extending in the row direction. The plurality of pixels may be connected to the CDS 130 through a plurality of column lines extending in the column direction. The pixel array 200 may include at least one pixel arranged in the row direction and the column direction. For example, the pixel array 200 may be arranged in a two-dimensional (2D) pixel array in which a plurality of unit pixels includes rows and columns.

The plurality of unit pixels included in the pixel array 200 may convert optical signals into electrical signals, and may be connected to a specific internal pixel circuit.

The pixel array 200 may receive a pixel control signal including a row selection signal, a pixel reset signal, a row transfer signal, etc. from the row driver 120. At least one pixel included in the row that is selected by the row driver 120 according to the pixel control signal may perform a specific operation in response to the row selection signal, the pixel reset signal, and the row transfer signal.

The CDS 130 may receive the reference signal and the image signal, each of which corresponds to the columns of the pixel array 200, and may sample levels of the reference signal and the image signal. In the image sensing device designed to use CMOS(s), the CDS 130 may sample a pixel signal twice to remove a difference between these two samples, and may perform correlated double sampling to remove undesired offset values of pixels such as fixed noise. For example, the CDS 130 may compare pixel output voltages obtained before and after photocharges generated by incident light are accumulated in the floating diffusion region to remove undesired offset values, so that the pixel output voltages based on the incident light can be measured.

The CDS 130 may transmit reference signals and image signals, which are generated in columns based on a timing signal and a control signal of the timing controller 110, to the ADC 140 as CDS signals.

The ADC 140 may convert analog CDS signals received from the CDS 130 into digital signals, and may output the resultant digital signals.

The output buffer 150 may temporarily hold and output digital signals provided from the ADC 140.

The column driver 160 may select columns from the output buffer 150 based on a timing signal and a control signal of the timing controller 110, and may control the temporarily held digital signals to be output according to the selection order.

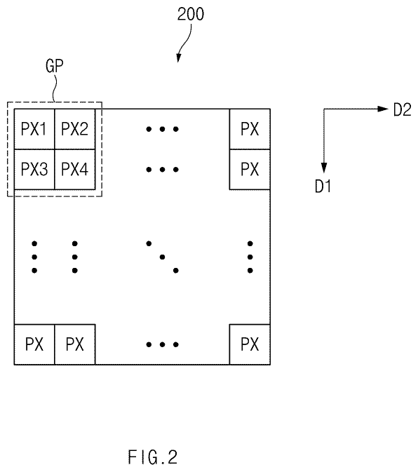

FIG. 2 is a plan view illustrating an example of the pixel array 200 shown in FIG. 1 based on some implementations of the disclosed technology.

Referring to FIGS. 1 and 2, the pixel array 200 may include, for example, a structure in which a plurality of pixels (PXs) is arranged in a two-dimensional (2D) matrix structure in a first direction D1 and a second direction D2. The pixel array 200 may include a pixel group (GP) in which four pixels (PX1, PX2, PX3, PX4) are arranged in a (2×2) matrix structure. The pixel array 200 may include M pixels (PXs) arranged in the first direction D1 (where ‘M’ is an integer of 2 or greater). The pixel array 200 may include N pixels (PXs) arranged in the second direction D2 (where ‘N’ is an integer of 2 or greater).

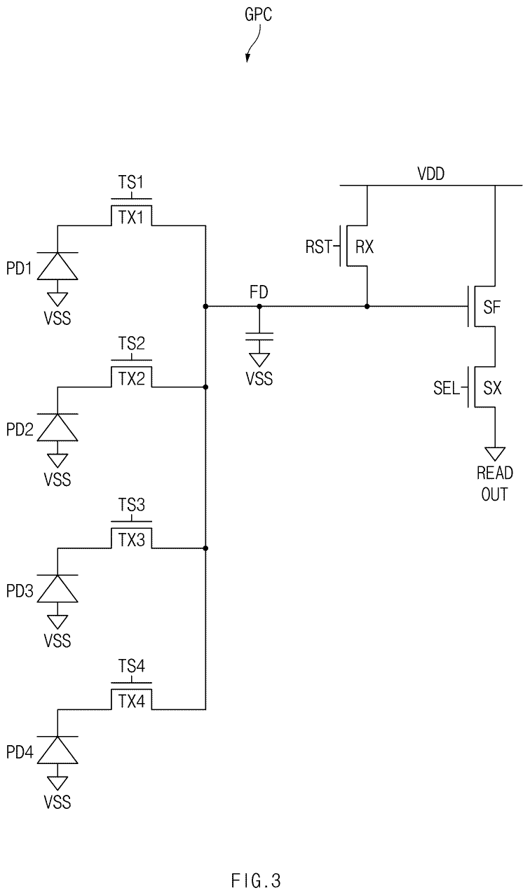

The pixel group (GP) may include a first pixel (PX1), a second pixel (PX2), a third pixel (PX3), and a fourth pixel (PX4). For example, in the pixel group GP, the first to fourth pixels (PX1˜PX4) may be arranged in a (2×2) matrix structure. The pixel group (GP) may be repeatedly arranged in the pixel array 200 along the first direction D1 and the second direction D2. A more detailed description of the pixel group (GP) will be given below with reference to the drawings below FIG. 3.

FIG. 3 is a circuit diagram illustrating an example of the pixel group (GP) shown in FIG. 2 based on some implementations of the disclosed technology.

Referring to FIGS. 2 and 3, a pixel group circuit diagram (GPC) of FIG. 3 may be a diagram showing an embodiment of a circuit diagram modeling shared pixel(s) corresponding to a pixel group (see ‘GP’ of FIG. 2). In this example, the shared pixel may conceptually include a plurality of adjacent pixels (e.g., PX1˜PX4) sharing at least one element. The pixel group circuit (GPC) may include first to fourth photoelectric conversion elements (PD1˜PD4), first to fourth transfer transistors (TX1˜TX4), a shared floating diffusion region (FD), a shared reset transistor (RX), a shared source follower transistor (SF), and a shared selection transistor (SEL).

The first to fourth photoelectric conversion elements (PD1˜PD4) may absorb incident light, and may generate and accumulate photocharges corresponding to the received light, e.g., the intensity of incident light, through photoelectric conversion of the incident light. For example, each of the first to fourth photoelectric conversion elements (PD1˜PD4) may be implemented as a photodiode, a phototransistor, a photogate, or a combination thereof. In FIG. 3, each of the first to fourth photoelectric conversion elements (PD1˜PD4) is exemplarily illustrated as a photodiode.

The first transfer transistor (TX1) may be connected between the first photoelectric conversion element (PD1) and the shared floating diffusion region (FD), and may transfer photocharges generated by the first photoelectric conversion element (PD1) to the shared floating diffusion region (FD) in response to a first transfer signal (TS1). The first transfer transistor (TX1) may be turned on in response to a first transfer signal (TS1) of a logic high level (e.g., 1). The first transfer transistor (TX1) may be turned off in response to the first transfer signal (TS1) of a logic low level (e.g., 0). In some implementations, the logic high level may refer to a voltage level that causes a voltage between the gate and the drain (or a voltage between the gate and the source) of the transistor to be equal to or greater than a threshold voltage of the transistor. In addition, the logic low level may refer to a voltage level that causes a voltage between the gate and the drain (or a voltage between the gate and the source) of the transistor to be less than a threshold voltage of the transistor. When the first transfer transistor (TX1) is turned on, photocharges generated by the first photoelectric conversion element (PD1) may move to the shared floating diffusion region (FD).

The second transfer transistor (TX2) may be connected between the second photoelectric conversion element (PD2) and the shared floating diffusion region (FD), and may transfer photocharges generated by the second photoelectric conversion element (PD2) to the shared floating diffusion region (FD) in response to a second transfer signal (TS2). The second transfer transistor (TX2) may be turned on in response to a second transfer signal (TS2) of a logic high level. The second transfer transistor (TX2) may be turned off in response to the second transfer signal (TS2) of a logic low level. When the second transfer transistor (TX2) is turned on, photocharges generated by the second photoelectric conversion element (PD2) may move to the shared floating diffusion region (FD).

The third transfer transistor (TX3) may be connected between the third photoelectric conversion element (PD3) and the shared floating diffusion region (FD), and may transfer photocharges generated by the third photoelectric conversion element (PD3) to the shared floating diffusion region (FD) in response to a third transfer signal (TS3). The third transfer transistor (TX3) may be turned on in response to a third transfer signal (TS3) of a logic high level. The third transfer transistor (TX3) may be turned off in response to the third transfer signal (TS3) of a logic low level. When the third transfer transistor (TX3) is turned on, photocharges generated by the third photoelectric conversion element (PD3) may move to the shared floating diffusion region (FD).

The fourth transfer transistor (TX4) may be connected between the fourth photoelectric conversion element (PD4) and the shared floating diffusion region (FD), and may transfer photocharges generated by the fourth photoelectric conversion element (PD4) to the shared floating diffusion region (FD) in response to a fourth transfer signal (TS4). The fourth transfer transistor (TX4) may be turned on in response to a fourth transfer signal (TS4) of a logic high level. The fourth transfer transistor (TX4) may be turned off in response to the fourth transfer signal (TS4) of a logic low level. When the fourth transfer transistor (TX4) is turned on, photocharges generated by the fourth photoelectric conversion element (PD4) may move to the shared floating diffusion region (FD).

The shared reset transistor (RX) may be connected between the power supply voltage (VDD) and the shared floating diffusion region (FD), and may reset the voltage of the shared floating diffusion region (FD) to the power supply voltage (VDD) in response to a pixel reset signal (RST). The shared reset transistor (RX) may be turned on in response to a pixel reset signal (RST) of a logic high level. The reset transistor (RX) may be turned off in response to the pixel reset signal (RST) of a logic low level. When the shared reset transistor (RX) is turned on, the voltage of the shared floating diffusion region (FD) may be reset to the power supply voltage (VDD).

The shared source follower transistor (SF) may be connected between the power supply voltage (VDD) and the select transistor (SX). A voltage corresponding to photocharges stored in the shared floating diffusion region (FD) may be applied to a gate terminal of the shared source follower transistor (SF). When the shared source follower transistor (SF) is turned on, the shared source follower transistor (SF) may amplify a potential change of the shared floating diffusion region (FD) and may transfer the amplified potential to the shared selection transistor (SX).

The shared selection transistor (SX) may be connected between the shared source follower transistor (SF) and the pixel signal output terminal (not shown), and may serve to select pixels to be read out in row units in response to the row selection signal (SEL). The shared selection transistor (SX) may be turned on or turned off depending on a voltage level of the row select signal (SEL). When the shared selection transistor (SX) is turned on, the shared selection transistor (SX) may output an electrical signal amplified by the source follower transistor (SF) to a pixel signal output terminal.

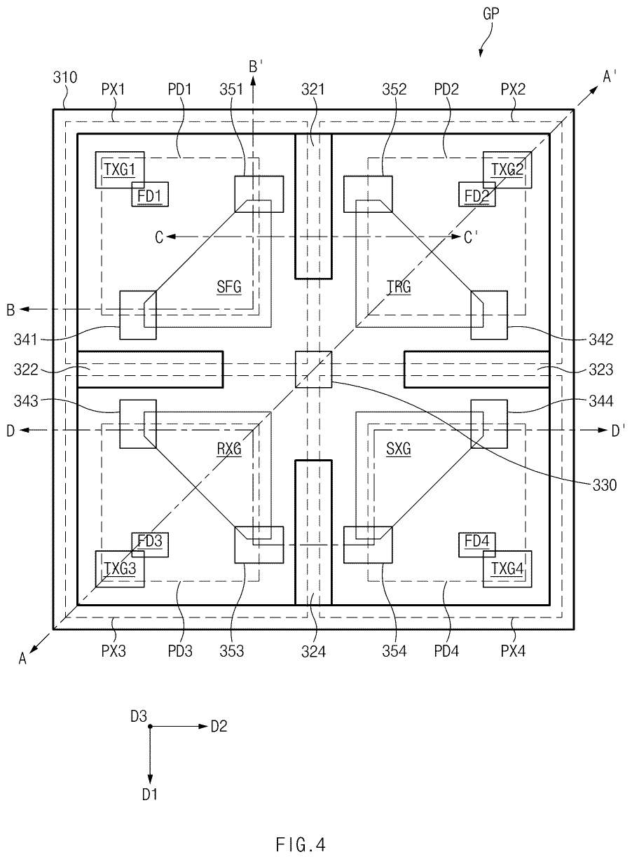

FIG. 4 is a plan view illustrating an example of the pixel group (GP) shown in FIG. 2 based on some implementations of the disclosed technology.

Referring to FIGS. 2 to 4, the pixel group (GP) may have a structure in which the first to fourth pixels (PX1˜PX4) are arranged in a (2×2) matrix structure. The pixel group (GP) may be surrounded by a first pixel isolation structure 310. A second pixel isolation structure 321 may be disposed at a boundary between the first pixel (PX1) and the second pixel (PX2). The second pixel isolation structure 321 may be in contact with the first pixel isolation structure 310 and may extend in the first direction D1. A third pixel isolation structure 322 may be disposed at a boundary between the first pixel (PX1) and the third pixel (PX3). The third pixel isolation structure 322 may be in contact with the first pixel isolation structure 310 and may extend in the second direction D2. A fourth pixel isolation structure 323 may be disposed at a boundary between the second pixel (PX2) and the fourth pixel (PX4). The fourth pixel isolation structure 323 may be in contact with the first pixel isolation structure 310 and may extend in a direction opposite to the second direction D2. A fifth pixel isolation structure 324 may be disposed at a boundary between the third pixel (PX3) and the fourth pixel (PX4). The fifth pixel isolation structure 324 may be in contact with the first pixel isolation structure 310 and may extend in a direction opposite to the first direction D1.

Each of the first to fifth pixel isolation structures (310, 321, 322, 323, 324) may include an insulation material (e.g., polysilicon). The second to fifth pixel isolation structures (321˜324) may be spaced apart from each other.

The first pixel isolation structure 310 may prevent crosstalk between adjacent pixel groups in the pixel array (see 200 of FIG. 1). The second pixel isolation structure 321 may prevent crosstalk between the first pixel (PX1) and the second pixel (PX2). The third pixel isolation structure 322 may prevent crosstalk between the first pixel (PX1) and the third pixel (PX3). The fourth pixel isolation structure 323 may prevent crosstalk between the second pixel (PX2) and the fourth pixel (PX4). The fifth pixel isolation structure 324 may prevent crosstalk between the third pixel (PX3) and the fourth pixel (PX4).

The gate (TXG1) of the first transfer transistor may refer to a gate structure of the first transfer transistor (TX1) shown in FIG. 3. The gate (TXG2) of the second transfer transistor may refer to a gate structure of the second transfer transistor (TX2) shown in FIG. 3. The gate (TXG3) of the third transfer transistor may refer to a gate structure of the third transfer transistor (TX3) shown in FIG. 3. The gate (TXG4) of the fourth transfer transistor may refer to a gate structure of the fourth transfer transistor (TX4) shown in FIG. 3. The gate (SFG) of the shared source follower transistor may refer to a gate structure of the shared source follower transistor (SF) shown in FIG. 3. The gate (RXG) of the shared reset transistor may refer to a gate structure of the shared reset transistor (RX) shown in FIG. 3. The gate (SXG) of the shared selection transistor may refer to a gate structure of the shared selection transistor (SX) shown in FIG. 3. Each of the gate (SFG) of the shared source follower transistor, the gates (TXG1˜TXG4) of the first to fourth transfer transistors, the gate (RXG) of the shared reset transistor, and the gate (SXG) of the shared selection transistor may include an oxide layer and an electrode layer disposed over the oxide layer. The first to fourth floating diffusion regions (FD1˜FD4) may be connected to each other by electrical interconnect lines. When the first to fourth floating diffusion regions (FD1˜FD4) are modeled in a circuit diagram, the shared floating diffusion regions of FIG. 3 may be illustrated as the shared floating diffusion region (FD).

The shared floating diffusion region (FD) may refer to a region that converts charges into voltage, and may accumulate charge due to a junction capacitor included therein. As an example, the shared floating diffusion region (FD) may be a doped region that is within a semiconductor substrate or is supported by the semiconductor substrate. When the semiconductor substrate has a first conductivity type (e.g., P-type), the shared floating diffusion region (FD) may have a second conductivity type (e.g., N-type). The shared floating diffusion region (FD) may be one floating diffusion region formed by electrical interconnect lines that can interconnect the first to fourth floating diffusion regions (FD1˜FD4).

The first pixel (PX1) may include a first photoelectric conversion element (PD1), a first floating diffusion region (FD1), a source region 341 of the shared source follower transistor, and a drain region 351 of the shared source follower transistor. The first pixel (PX1) may overlap the gate (TXG1) of the first transfer transistor and the gate (SFG) of the shared source follower transistor.

The second pixel (PX2) may include a second photoelectric conversion element (PD2), a second floating diffusion region (FD2), a source region 342 of the shared pixel transistor, and a drain region 352 of the shared pixel transistor. The second pixel (PX2) may overlap the gate (TXG2) of the second transfer transistor and the gate (TRG) of the shared pixel transistor.

The third pixel (PX3) may include a third photoelectric conversion element (PD3), a third floating diffusion region (FD3), a source region 343 of the shared reset transistor, and a drain region 353 of the shared reset transistor. The third pixel (PX3) may overlap the gate (TXG3) of the third transfer transistor and the gate (RXG) of the shared reset transistor.

The fourth pixel (PX4) may include a fourth photoelectric conversion element (PD4), a fourth floating diffusion region (FD4), a source region 344 of the shared selection transistor, and a drain region 354 of the shared selection transistor. The fourth pixel (PX4) may overlap the gate (TXG4) of the fourth transfer transistor and the gate (SXG) of the shared selection transistor.

The pixel group according to the present embodiment may also include a structure designed by interchanging the positions of the source and drain regions of each of the first to fourth pixels (PX1˜PX4). In addition, the positions of the gate (SFG) of the shared source follower transistor, the gate (TRG) of the shared pixel transistor, the gate (RXG) of the shared reset transistor, and the gate (SXG) of the shared selection transistor are merely an example, and may be interchanged as needed. For example, according to another embodiment of the disclosed technology, the positions of the gate (RXG) of the shared reset transistor and the gate (SXG) of the shared selection transistor (SX) shown in FIG. 4 may be interchanged. Hereinafter, the following embodiment in which the gate (SFG) of the shared source follower transistor (SF) overlaps the first pixel (PX1), the gate (TRG) of the shared pixel transistor overlaps the second pixel (PX2), the gate (RXG) of the shared reset transistor (RX) overlaps the third pixel (PX3), and the gate (SXG) of the shared selection transistor (SX) overlaps the fourth pixel (PX4) will be described in detail with reference to the attached drawings.

In an example, the body bias region 330 may be disposed at the center of a (2×2) matrix structure in which the first to fourth pixels (PX1˜PX4) are arranged. In the example, the body bias region 330 may be disposed in the vicinity of four corners of the first to fourth pixels (PX1˜PX4) that are disposed in a center area of the pixel group (GP). The body bias region 330 may be defined by a first region between the boundary of the first pixel (PX1) and the boundary of the second pixel (PX2) and a second region between the boundary of the first pixel (PX1) and the boundary of the third pixel (PX3). For example, referring to FIG. 4, the first region between the boundary of the first pixel (PX1) and the boundary of the second pixel (PX2) extends along the first direction (D1) to form an extended first region and the second region between the boundary of the first pixel (PX1) and the boundary of the third pixel (PX3) extends along the second direction D2 to form an extended second region. In the example, the body bias region 330 may be disposed where the extended first region meets the extended second region.

The gate (TXG1) of the first transfer transistor may overlap the first photoelectric conversion element (PD1). A minimum distance between the gate (TXG1) of the first transfer transistor and the body bias region 330 may be greater than a minimum distance between the gate (SFG) of the shared source follower transistor and the body bias region 330.

The gate (TXG2) of the second transfer transistor may overlap the second photoelectric conversion element (PD2). A minimum distance between the gate (TXG2) of the second transfer transistor and the body bias region 330 may be greater than a minimum distance between the gate (TRG) of the shared pixel transistor and the body bias region 330.

The gate (TXG3) of the third transfer transistor may overlap the third photoelectric conversion element (PD3). A minimum distance between the gate (TXG3) of the third transfer transistor and the body bias region 330 may be greater than a minimum distance between the gate (RXG) of the shared reset transistor and the body bias region 330.

The gate (TXG4) of the fourth transfer transistor may overlap the fourth photoelectric conversion element (PD4). A minimum distance between the gate (TXG4) of the fourth transfer transistor and the body bias region 330 may be greater than a minimum distance between the gate (SXG) of the shared selection transistor and the body bias region 330.

The first floating diffusion region (FD1) may overlap the gate (TXG1) of the first transfer transistor (TX1). The second floating diffusion region (FD2) may overlap the gate (TXG2) of the second transfer transistor (TX2). The third floating diffusion region (FD3) may overlap the gate (TXG3) of the third transfer transistor (TX3). The fourth floating diffusion region (FD4) may overlap the gate (TXG4) of the fourth transfer transistor (TX4).

Although FIG. 4 illustrates that the first to fourth floating diffusion regions (FD1˜FD4) are separated from each other, other implementations are also possible, and the first to fourth floating diffusion regions (FD1˜FD4) may be connected to each other through electrical interconnect lines and may also be modeled as only one floating diffusion node (FD) as shown in the circuit diagram of FIG. 3.

The oxide layer of the gate (SFG) of the shared source follower transistor may be thinner than the oxide layer of the gate of other transistors. For example, the oxide layer of the gate (SFG) of the shared source follower transistor may be thinner than the oxide layer of the gate (RXG) of the shared reset transistor. In another example, the oxide layer of the gate (SFG) of the shared source follower transistor may be thinner than the oxide layer of the gate (SXG) of the shared selection transistor. As the gate oxide layer of the shared source follower transistor becomes thinner, capacitance of the gate oxide layer increases, making it possible to provide an image sensing device with less pixel signal noise.

Each of the shared source follower transistor (SF), the shared pixel transistor, the shared reset transistor (RX), and the shared selection transistor (SX) may have source regions (341˜344) and drain regions (351˜354). The positional relationship between the source regions (341˜344) and the drain regions (351˜354) will hereinafter be exemplarily described by the source region 341 and the drain region 351 of the shared source follower transistor (SF).

Each of the source region 341 and the drain region 351 of the shared source follower transistor (SF) may overlap the gate (SFG) of the shared source follower transistor. The source region 341 of the shared source follower transistor may be disposed to be biased in a direction opposite to the second direction D2 from the gate (SFG) of the shared source follower transistor (SF). The drain region 351 of the shared source follower transistor (SF) may be disposed to be biased in a direction opposite to the first direction D1 from the gate (SFG) of the shared source follower transistor (SF). The source region 341 and the drain region 351 of the shared source follower transistor (SF) may be spaced apart from each other. For example, the source region 341 and the drain region 351 of the shared source follower transistor (SF) may be disposed apart from each other in a diagonal direction. Such arrangement of the source region 341 and the drain region 351 may ensure that the gate (SFG) area of the shared source follower transistor is as wide as possible. The above-described arrangement is an example only and other implementations are also possible. When the gate (SFG) area of the shared source follower transistor (SF) increases and the shared source follower transistor is turned on, the arrangement relationship may be adjusted so that the length of a channel, which can be formed under the gate (SFG) of the shared source follower transistor, can be made as long as possible.

When the length of the channel is secured, the short channel effect may be reduced and the reliability of the shared source follower transistor (SF) may be increased. As the gate (SFG) area of the shared source follower transistor (SF) becomes thinner, noise of the pixel signal may be reduced.

The shared pixel transistor may be used as a dual conversion gain (DCG) transistor according to one embodiment (hereinafter referred to as “Embodiment 1”). The DCG transistor may change the capacitance of the shared floating diffusion region (FD). For example, when a voltage greater than the threshold voltage is applied to the gate (TRG) of the DCG transistor, the DCG transistor may change the capacitance of the shared floating diffusion region (FD). At least one of the source region 342 and the drain region 352 of the DCG transistor may be connected to the shared floating diffusion region (FD). The first embodiment (Embodiment 1) of the disclosed technology may be advantageous in that not only noise of the pixel signal is reduced by increasing the gate (SFG) area of the shared source follower transistor, but also a double conversion gain (DCG) can be implemented by the shared pixel transistor.

The shared pixel transistor may be used as another shared source follower transistor according to another embodiment (hereinafter referred to as “Embodiment 2”). In Embodiment 2, the two shared source follower transistors may be connected in parallel. When two gates (SFG, TRG) of the shared source follower transistor are used, noise of the pixel signal may be further reduced because the gate area of the shared source follower transistor further increases in width as compared to the other shared source follower transistor that does not use two gates.

In Embodiment 2, even when the second pixel isolation structure 321 overlaps the space between the gate (SFG) of the shared source follower transistor (SF) and the gate (TRG) of the shared pixel transistor, the area of the gates (SFG, TRG) of the shared source follower transistor can increase in size, and crosstalk between the first pixel (PX1) and the second pixel (PX2) can be prevented because the second pixel isolation structure 321 is extended.

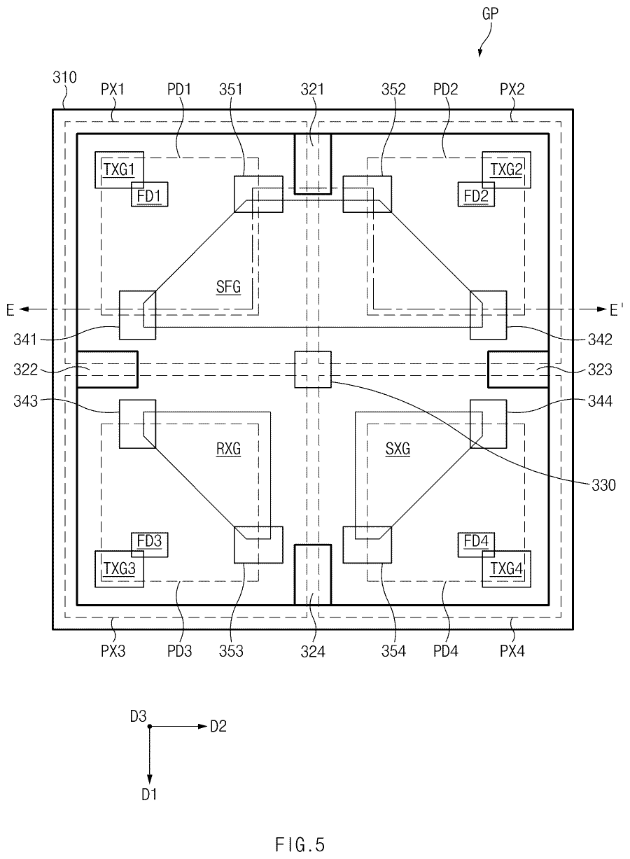

FIG. 5 is a plan view illustrating an example of another embodiment of the pixel group shown in FIG. 2 based on some implementations of the disclosed technology.

Hereinafter, the structure of FIG. 5 will be described centering upon differences between FIG. 5 and FIG. 4 to avoid duplication of explanation.

Referring to FIGS. 4 and 5, in the embodiment of FIG. 5 (hereinafter referred to as “Embodiment 3”), the gate (TRG of FIG. 4) of the shared pixel transistor is not disposed in the pixel group, and the gate (SFG) of the shared source follower transistor is arranged to overlap not only the first pixel (PX1) but also the second pixel (PX2). In the example, the second pixel isolation structure 321 according to Embodiment 3 may extend in the first direction D1. In the example, the second pixel isolation structure 321 has a shorter length than that of the second embodiment (Embodiment 2).

The gate (SFG) of the shared source follower transistor (SF) may overlap the first pixel (PX1) and the second pixel (PX2). The shortest distance between the gate (SFG) of the shared source follower transistor (SF) and the body bias region 330 disposed at the center of the (2×2) matrix structure may be shorter than the shortest distance between the second pixel isolation structure 321 and the body bias region 330. Additionally, the longest distance in the first direction D1 between the gate (SFG) of the shared source follower transistor and the body bias region 330 may be shorter than the shortest distance in the first direction D1 between the second pixel isolation structure 321 and the body bias region 330.

The second pixel isolation structure 321 may extend in the first direction D1 within a region in which the second pixel isolation structure 321 is spaced apart from the gate (SFG) of the shared source follower transistor (SF). The second pixel isolation structure 321 may be in contact with the first pixel isolation structure 310.

The image sensing device according to the third embodiment (hereinafter referred to as “Embodiment 3”) can secure a larger area of the gate (SFG) of the shared source follower transistor, so that the image sensor can be implemented with less noise.

The oxide layer of the gate (SFG) of the shared source follower transistor may be thinner than the oxide layer of the gate (RXG) of the shared reset transistor or the oxide layer of the gate (SXG) of the shared selection transistor. As the gate oxide layer becomes thinner, the capacitance of the gate oxide layer increases, making it possible to provide an image sensing device with less noise.

Although the source and drain regions (341, 342, 351, 352) that overlap the gate (SFG) of the shared source follower transistor (SF) are regions spaced apart from one another, other implementations are also possible, and two source regions (341, 342) and two drain regions (351, 352) are respectively electrically connected to each other through electrical interconnect lines so that one source region and one drain region can be implemented.

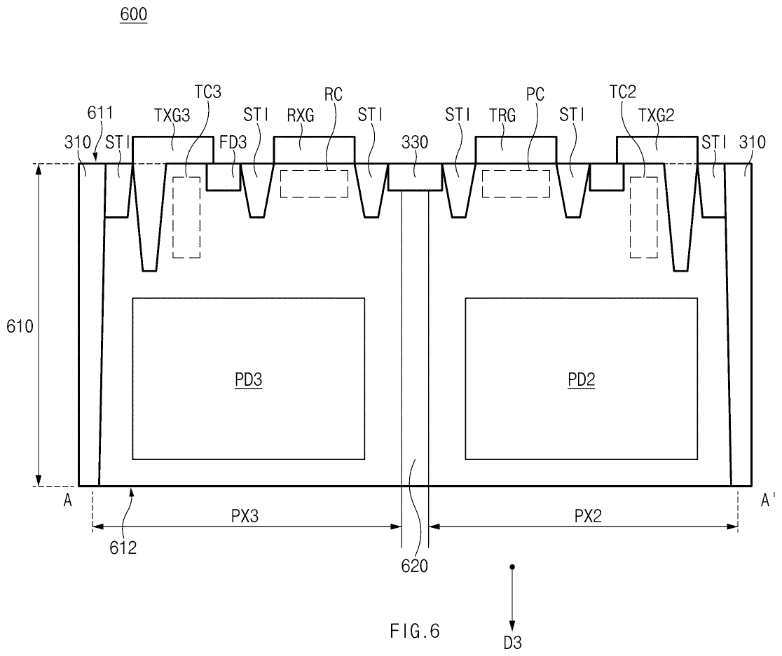

FIG. 6 is a cross-sectional view illustrating an example of the pixel group taken along the line A-A′ of FIG. 4 based on some implementations of the disclosed technology.

Referring to FIGS. 4 and 6, a first cross-section 600 of the pixel group (GP) taken along the line A-A′ shown in FIG. 4 may be one example of a cross-section of the pixel group (GP) taken along the line A-A′.

The first cross-section 600 may include a substrate region 610, a gate (TXG3) of the third transfer transistor, a gate (RXG) of the shared reset transistor, a gate (TRG) of the shared pixel transistor, and a gate (TXG2) of the second transfer transistor. Those transistors and other circuit elements can be formed on or supported by the substrate region 610.

The substrate region 610 may include a first surface 611 (or a front side) to which the gate of the transistor or electrical interconnect lines can be connected, and a second surface (or a back side) facing (or opposite to) the first surface to allow external light to be incident thereupon. The substrate region 610 may include a first pixel isolation structure 310, a pixel insulation structure (STI), a body region 620, a second photoelectric conversion element (PD2), a third photoelectric conversion element (PD3), and a second floating diffusion region (FD2), a third floating diffusion region (FD3), a second transfer channel (TC2), a third transfer channel (TC3), a shared reset channel (RC), a shared pixel channel (PC), and a body bias region 330.

The first pixel isolation structure 310 may have a structure recessed from the first surface 611 in the third direction D3. The depth at which the first pixel isolation structure 310 is recessed may be equal to or smaller than the thickness of the substrate region 610 in the third direction D3. FIG. 6 shows an embodiment in which the first pixel isolation structure 310 is recessed through the substrate region 610.

The pixel insulation structure (STI) may have a structure that is recessed from the first surface in the third direction D3. The pixel insulation structure (STI) may be arranged to be adjacent to the gate (RXG) of the shared reset transistor, the gates (TXG2, TXG3) of the second and third transfer transistors, the gate (TRG) of the shared pixel transistor, and the first pixel isolation structure 310. The pixel insulation structure (STI) may include an insulation material (e.g., SiO₂). The pixel insulation structure (STI) may prevent leakage of charges when charges move through each of the channels that may be formed in the body region 620.

The body region 620 may be at least a portion of the remaining regions other than the first pixel isolation structure 310, the pixel insulation structure (STI), the second and third photoelectric conversion elements (PD2, PD3), the second and third floating diffusion regions (FD2, FD3), the body bias region 330, and the recessed portions of the gates (TXG2, TXG3) of the second and third transfer transistors. The body region 610 may be a region that has a first conductivity type (e.g., P-type) and includes silicon (Si).

The second photoelectric conversion element (PD2) may be disposed within a range corresponding to the second pixel (PX2). The second photoelectric conversion element (PD2) may be a region in which photocharges corresponding to incident light are generated when light is incident upon the second surface 612 from the outside. The second photoelectric conversion element (PD2) may be a region having a second conductivity type (e.g., N-type).

The second floating diffusion region (FD2) may be disposed in the substrate region 610 corresponding to the second pixel (PX2) region. The second floating diffusion region (FD2) may be disposed to partially overlap the gate (TXG2) of the second transfer transistor on the first surface 611. The second floating diffusion region (FD2) may be a region having a second conductivity type.

The third floating diffusion region (FD3) may be disposed in the substrate region 610 corresponding to the third pixel (PX3) region. The third floating diffusion region (FD3) may be arranged to partially overlap the gate (TXG3) of the third transfer transistor on the first surface 611. The third floating diffusion region (FD3) may be a region having a second conductivity type.

A second transfer channel (TC2) may be a carrier movement path through which photocharges generated by the second photoelectric conversion element (PD2) move to the second floating diffusion region (FD2) when the second transfer transistor (TX2) is turned on.

A third transfer channel (TC3) may be a carrier movement path through which photocharges generated by the third photoelectric conversion element (PD3) move to the third floating diffusion region (FD3) when the third transfer transistor (TX3) is turned on.

A shared reset channel (RC) may be a carrier movement path through which photocharges accumulated in the shared floating diffusion region (see FD of FIG. 3) escape to the outside of the floating diffusion region (FD) when the shared reset transistor (RX) is turned on.

A shared pixel channel (PC) may be a carrier movement path through which charges move between the source region 342 and the drain region 352 of the shared pixel transistor when the shared pixel transistor is turned on via its gate TRG. For example, the shared pixel transistor may be a DCG transistor. In another example, the shared pixel transistor may be another source follower transistor.

Although not shown in FIG. 6, one or more electrical interconnect lines may be disposed in a direction opposite to the third direction D3 from the first surface 611. The one or more electrical interconnect lines may be appropriately implemented to achieve technical features of FIGS. 3 and 4. For example, the second floating diffusion region (FD2) and the third floating diffusion region (FD3) are shown as being spaced apart from each other in the first cross-section 600, but the scope of the disclosed technology is not limited thereto, and it should be noted that the second floating diffusion region (FD2) and the third floating diffusion region (FD3) are connected to each other through electrical interconnect lines. For example, a contact to which a voltage can be applied may be connected to each of the gates (TXG2, TXG3, RXG, TRG) of the transistor.

The body bias region 330 may be disposed adjacent to the first surface 611 in the vicinity of two corners of the second pixel (PX2) and the third pixel (PX3) that are disposed in a diagonal direction. The body bias region 330 may have a first conductivity type. The body bias region 330 may have a greater concentration of impurities having the first conductivity type than the body region 620. The body bias region 330 may be a region to which the body bias voltage is applied. The body bias voltage may refer to an external voltage applied to the body bias region 330. When the body bias voltage is applied to the body bias region 330, for example, noise of the pixel signal can be reduced and the number of occurrences of the dark current can also be reduced.

The gate (TXG2) of the second transfer transistor may include a planar portion disposed over the first surface 611 while overlapping the second pixel (PX2), and an extension portion recessed in the third direction D3. The gate (TXG2) of the second transfer transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide and silicon-based nitride, and may be a material that can electrically isolate the gate electrode layer and the body region 620 from each other. At least a portion of the gate insulation layer may be disposed under the gate electrode layer. In FIG. 5 and below, in order to prevent confusion of the drawings, the gate electrode layer and the gate insulation layer are not shown separately but are shown as the gate (TXG2) of one second transfer transistor. The structure including the recessed shape of the gate (TXG2) of the second transfer transistor is merely an example, and various modification and variations are possible.

The gate (TXG3) of the third transfer transistor may include a planar portion disposed over the first surface 611 while overlapping the third pixel (PX3), and an extension portion recessed in the third direction D3. The gate (TXG3) of the third transfer transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide and silicon-based nitride, and may be a material that can electrically isolate the gate electrode layer and the body region 620 from each other. At least a portion of the gate insulation layer may be disposed under the gate electrode layer. In FIG. 6 and below, in order to prevent confusion of the drawings, the gate electrode layer and the gate insulation layer are not shown separately but are shown as the gate (TXG3) of one third transfer transistor. The structure including the recessed shape of the gate (TXG3) of the third transfer transistor is merely an example, and various modification and variations are possible.

The gate (RXG) of the shared reset transistor may overlap the third pixel (PX3) and may be disposed over the first surface 611. The gate (RXG) of the shared reset transistor may overlap the third photoelectric conversion element (PD3). The gate (RXG) of the shared reset transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide and silicon-based nitride, and may be a material that can electrically isolate the gate electrode layer and the body region 620 from each other. At least a portion of the gate insulation layer may be disposed under the gate electrode layer. In FIG. 6 and below, in order to prevent confusion of the drawings, the gate electrode layer and the gate insulation layer are not shown separately but are shown as the gate (RXG) of one shared reset transistor.

The gate (TRG) of the shared pixel transistor may overlap the second pixel (PX2) and may be disposed over the first surface 611. The gate (TRG) of the shared pixel transistor may overlap the second photoelectric conversion element (PD2). The gate (TRG) of the shared pixel transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide and silicon-based nitride, and may be a material that can electrically isolate the gate electrode layer and the body region 620 from each other. At least a portion of the gate insulation layer may be disposed under the gate electrode layer. In FIG. 6 and below, in order to prevent confusion of the drawings, the gate electrode layer and the gate insulation layer are not shown separately but are shown as the gate (TRG) of one shared pixel transistor.

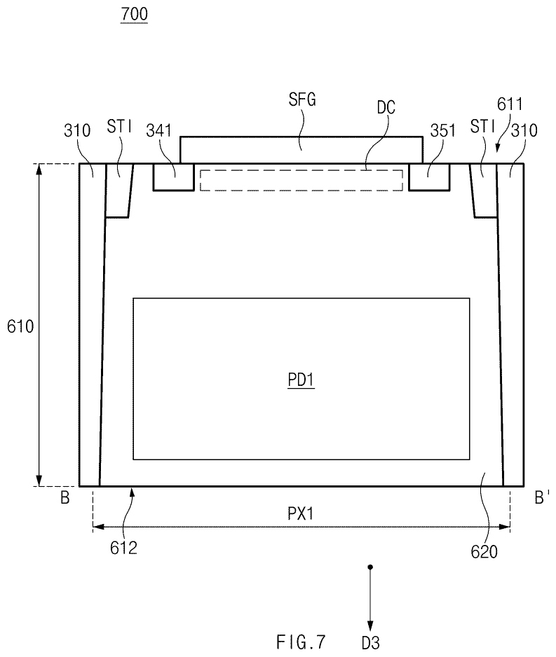

FIG. 7 is a cross-sectional view illustrating an example of the pixel group taken along the line B-B′ of FIG. 4 based on some implementations of the disclosed technology.

Referring to FIGS. 4, 6 and 7, a second cross-section 700 of the pixel group (GP) taken along the line B-B′ shown in FIG. 4 may be one example of a cross-section of the pixel group (GP) taken along the line B-B′. In order to prevent duplication of explanation, a detailed description of the same elements as those of FIG. 6 will herein be omitted for brevity.

The second cross-section 700 may include a substrate region 610 and a gate (SFG) of the shared source follower transistor.

The substrate region 610 may include a first pixel isolation structure 310, a pixel insulation structure (STI), a first photoelectric conversion element (PD1), a source region 341, a drain region 351, and a shared source follower channel (DC), and a body region 620.

The first photoelectric conversion element (PD1) may be disposed within a range corresponding to the first pixel (PX1). The first photoelectric conversion element (PD1) may be a region in which photocharges corresponding to incident light are generated when light is incident upon the second surface 612 from the outside. The first photoelectric conversion element (PD1) may be a region having a second conductivity type.

The source region 341 may be a source region of a shared source follower transistor. The source region 341 may be disposed to overlap a portion of the gate (SFG) of the shared source follower transistor in the vicinity of the first surface 611. The source region 341 may be a region having a second conductivity type.

The drain region 351 may be a drain region of a shared source follower transistor. The drain region 351 may be disposed to overlap another portion of the gate (SFG) of the shared source follower transistor in the vicinity of the first surface 611. The drain region 351 may be a region having a second conductivity type.

The gate (SFG) of the shared source follower transistor may overlap the first pixel (PX1) and may be disposed over the first surface 611. The gate (SFG) of the shared source follower transistor may overlap the first photoelectric conversion element (PD1) in the third direction D3. The gate (SFG) of the shared source follower transistor may overlap each of the source region 341 and the drain region 351.

When the shared source follower transistor (SF) is turned on, the shared source follower channel (DC) may be formed under the gate (SFG) of the shared source follower transistor. When the shared source follower channel (DC) is formed, carrier movement may occur between the source region 341 and the drain region 351, and the shared source follower channel (DC) may serve as a carrier movement path.

The gate (SFG) of the shared source follower transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide and silicon-based nitride, and may be a material that can electrically isolate the gate electrode layer and the body region 620 from each other. At least a portion of the gate insulation layer may be disposed under the gate electrode layer. In FIG. 7 and below, in order to prevent confusion of the drawings, the gate electrode layer and the gate insulation layer are not shown separately but are shown as the gate (SFG) of one shared source follower transistor.

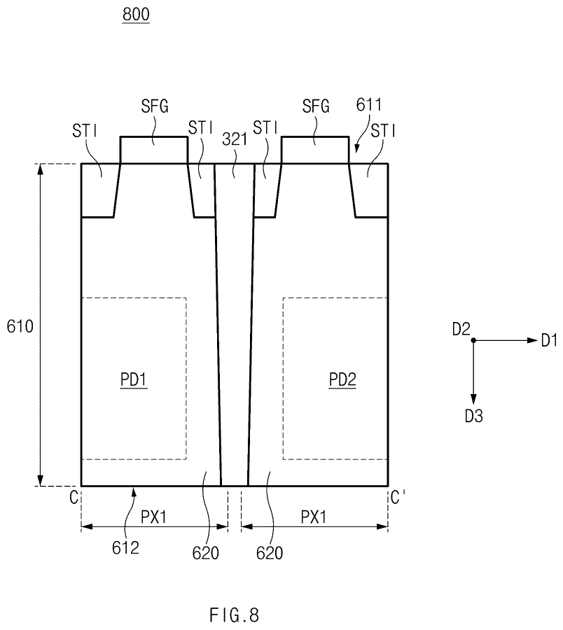

FIG. 8 is a cross-sectional view illustrating an example of the pixel group (GP) taken along the line C-C′ of FIG. 4 based on some implementations of the disclosed technology.

Referring to FIGS. 4 and 8, a third cross-section 800 of the pixel group (GP) taken along the line C-C′ shown in FIG. 4 may be one example of a cross-section of the pixel group (GP) taken along the line C-C′.

The third cross-section 800 may include a substrate region 610, a gate (SFG) of the shared source follower transistor, and a gate (TRG) of the shared pixel transistor.

The substrate region 610 may include first and second photoelectric conversion elements (PD1, PD2), a second pixel isolation structure 321, and a pixel insulation structure (STI).

The second pixel isolation structure 321 may have a structure recessed from the first surface 611 in the third direction D3 to prevent crosstalk between the first pixel (PX1) and the second pixel (PX2).

The gate (SFG) of the shared source follower transistor may overlap the first photoelectric conversion element (PD1) and may be disposed over the first surface 611. The gate (TRG) of the shared pixel transistor may overlap the second photoelectric conversion element (PD2) and may be disposed over the first surface 611.

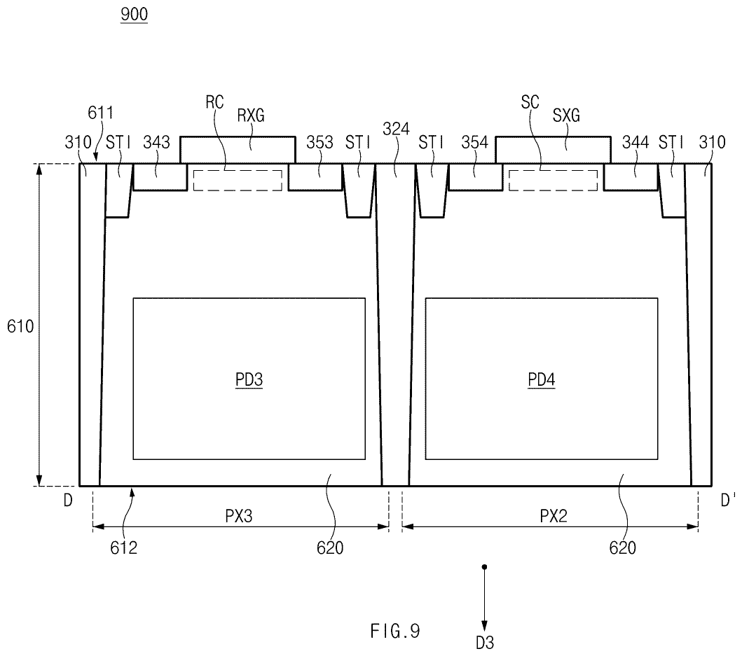

FIG. 9 is a cross-sectional view illustrating an example of the pixel group (GP) taken along the line D-D′ of FIG. 4 based on some implementations of the disclosed technology.

Referring to FIGS. 4 and 9, a fourth cross-section 900 of the pixel group (GP) taken along the line D-D′ shown in FIG. 4 may be one example of a cross-section of the pixel group (GP) taken along the line D-D′.

The fourth cross-section 900 may include a substrate region 610, a gate (RXG) of the shared reset transistor, and a gate (SXG) of the shared selection transistor.

The substrate region 610 may include a first pixel isolation structure 310, a fifth pixel isolation structure 324, a pixel insulation structure (STI), source and drain regions (343, 353) of the shared reset transistor, source and drain regions (344, 354) of the shared selection transistor, and third and fourth photoelectric conversion elements (PD3, PD4).

The fourth photoelectric conversion element (PD4) may be disposed within a range corresponding to the fourth pixel (PX4). The fourth photoelectric conversion element (PD4) may generate photocharges in response to incident light received from the outside through the second surface 612. The fourth photoelectric conversion element (PD4) may be a region having a second conductivity type.

One terminal of the source region 343 and the drain region 353 of the shared reset transistor may be connected to electrical interconnect lines connected to the power supply voltage (VDD of FIG. 3). The other terminal of the source region 343 and the drain region 353 of the shared reset transistor may be connected to electrical interconnect lines connected to the third floating diffusion region (FD3 of FIG. 4).

When the shared reset transistor is turned on, a shared reset channel (RC) may be formed under the gate (RXG) of the shared reset transistor. The shared reset channel (RC) may serve as a carrier movement path between the source region 343 and the drain region 353 of the shared reset transistor, and the shared floating diffusion region (FD) may be reset through the shared reset channel (RC).

One terminal from among the source region 344 and the drain region 354 of the shared selection transistor may be connected to electrical interconnect lines connected to one terminal of the shared source follower transistor (SF). The other terminal from among the source region 344 and the drain region 354 of the shared selection transistor may be connected to electrical interconnect lines for outputting electrical signals.

The gate (RXG) of the shared reset transistor may be disposed to overlap the third photoelectric conversion element (PD3) on the first surface 611, and the gate (SXG) of the shared selection transistor may be disposed to overlap the fourth photoelectric conversion element (PD4) on the first surface 611.

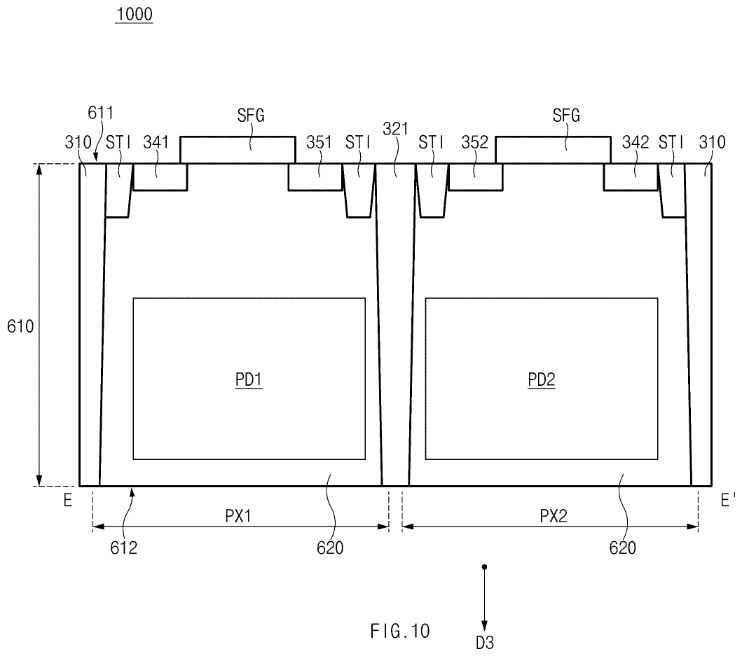

The gate (SXG) of the shared selection transistor may include a gate electrode layer and a gate insulation layer. The gate electrode layer may include at least one of conductive materials, for example, polysilicon, doped metal, silicide, or a combination thereof. The gate insulation layer may include at least one of insulation materials, for example, silicon-based oxide, or silicon-based nitride, and may be a material that can electrically isolate the gate electrode layer and the body region 620 from each other. At least a portion of the gate insulation layer may be disposed under the gate electrode layer. In FIGS. 9 and 10, in order to prevent confusion of the drawings, the gate electrode layer and the gate insulation layer are not shown separately but are shown as the gate (SXG) of one shared selection transistor.

FIG. 10 is a cross-sectional view illustrating an example of the pixel group (GP) taken along the line E-E′ of FIG. 5 based on some implementations of the disclosed technology.

Referring to FIGS. 4, 5 and 10, a fifth cross-section 1000 of the pixel group (GP) taken along the line E-E′ shown in FIG. 5 may be one example of a cross-section of the pixel group (GP) taken along the line E-E′.

The fifth cross-section 1000 may include a substrate region 610 and a gate (SFG) of the shared source follower transistor.

The substrate region 610 may include the first and second photoelectric conversion elements (PD1, PD2), the first pixel isolation structure 310, the second pixel isolation structure 321, the pixel insulation structure (STI), and source regions (341, 342) and drain regions (351, 352) of the shared source follower transistor.

Each of the source regions (341, 342) and the drain regions (351, 352) of the shared source follower transistor may overlap the gate (SFG) of the shared source follower transistor in the third direction D3. Among the source regions (341, 342) or the drain regions (351, 352), one region included in the first pixel (PX1) region may be connected to one region included in the second pixel (PX2) region through electrical interconnect lines. Among the source regions (341, 342) or the drain regions (351, 352), the other region included in the first pixel (PX1) region may be connected to the other region included in the second pixel (PX2) region through electrical interconnect lines. According to another embodiment, the source region 341 and the drain region 351 of the shared source follower transistor included in the first pixel (PX1) region may be connected to each other through electrical interconnect lines, and the source region 342 and the drain region 352 of the shared source follower transistor included in the second pixel (PX2) region may be connected to each other through electrical interconnect lines.

Each of the four regions (341, 342, 351, 352) corresponding to the source or drain region may be a region having a second conductivity type.

Two regions (e.g., the regions 351 and 352) from among the four regions (341, 342, 351, 352) corresponding to the source or drain regions may be omitted depending on the embodiment.

As is apparent from the above description, the image sensing device based on some implementations of the disclosed technology can be formed with a structure that secures a larger area for a gate region of a source follower transistor to reduce the amount of noise and effectively applies a bias voltage to a substrate in which one or more pixels are formed.

The embodiments of the disclosed technology may provide a variety of effects capable of being directly or indirectly recognized through the above-mentioned patent document.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
first to fourth pixels arranged in a (2×2) matrix structure in which the first pixel and the second pixel are adjacent to each other in a first direction and the first pixel and the third pixel are adjacent to each other in a second direction, and the first to fourth pixels configured to generating photocharges corresponding to incident light and configured to share at least one element; and
a body bias region disposed at a location defined by a first region between a boundary of the first pixel and a boundary of the second pixel and a second region between the boundary of the first pixel and a boundary of the third pixel, and the body bias region configured to receive a bias voltage as an input.

2. The image sensing device according to claim 1, further comprising:
a first pixel isolation structure configured to surround outer walls of the (2×2) matrix structure;
a second pixel isolation structure configured to contact the first pixel isolation structure, disposed between the first pixel and the second pixel, and spaced apart from the body bias region; and
a third pixel isolation structure configured to contact the first pixel isolation structure, disposed between the first pixel and the third pixel, and spaced apart from the body bias region.

3. The image sensing device according to claim 1, wherein:
the first pixel is configured to have a first photoelectric conversion element that generates photocharges in response to incident light;
the second pixel is configured to have a second photoelectric conversion element that generates photocharges in response to the incident light;
the third pixel is configured to have a third photoelectric conversion element that generates photocharges in response to the incident light; and
the fourth pixel is configured to have a fourth photoelectric conversion element that generates photocharges in response to the incident light.

4. The image sensing device according to claim 3, wherein the at least one element includes:
a shared floating diffusion region configured to store photocharges generated by each of the first to fourth photoelectric conversion elements; and
a shared source follower transistor including a gate that is configured to receive a voltage corresponding to the photocharges stored in the shared floating diffusion region, and is structured to overlap the first pixel.

5. The image sensing device according to claim 4, wherein:
the gate of the shared source follower transistor is configured to further overlap the second pixel.

6. The image sensing device according to claim 4, wherein:
the gate of the shared source follower transistor is spaced apart from the body bias region, and a shortest distance between the body bias region and the gate of the shared source follower transistor is shorter than a shortest distance between the body bias region and a center of the first pixel.

7. The image sensing device according to claim 4, wherein the at least one element further includes:
a shared reset transistor configured to reset the shared floating diffusion region and including a gate that is structured to overlap the second pixel.

8. The image sensing device according to claim 7, wherein:
each of the gate of the shared source follower transistor and the gate of the shared reset transistor includes an oxide layer,
wherein
the oxide layer of the gate of the shared source follower transistor is thinner than the oxide layer of the gate of the shared reset transistor.

9. The image sensing device according to claim 4, wherein the at least one element further includes:
a shared selection transistor including a gate which is structured to overlap the second pixel, a first terminal and a second terminal, wherein the first terminal is connected to the shared source follower transistor, and the shared source follower transistor is configured to output a pixel signal of each of the first to fourth pixels through the second terminal.

10. The image sensing device according to claim 9, wherein:
each of the gate of the shared source follower transistor and the gate of the shared selection transistor includes an oxide layer,
wherein
the oxide layer of the gate of the shared source follower transistor is thinner than the oxide layer of the gate of the shared selection transistor.

11. The image sensing device according to claim 4, wherein:
a source region of the shared source follower transistor is disposed in one direction with respect to the gate of the shared source follower transistor; and
a drain region of the shared source follower transistor is disposed in another direction with respect to the gate of the shared source follower transistor that is different from the one direction.

12. The image sensing device according to claim 4, wherein the at least one element further includes:
a shared dual conversion gain (DCG) transistor configured to vary capacitance of the shared floating diffusion region,
wherein
a gate of the shared DCG transistor is structured to overlap the second pixel.

13. An image sensing device comprising:
a semiconductor substrate configured to have a first surface upon which light is incident and a second surface opposite to the first surface;
first to fourth photoelectric conversion elements supported by the semiconductor substrate and arranged to be spaced apart from each other in a (2×2) matrix structure, each photoelectric conversion element configured to generate photocharges in response to the incident light;
a first pixel isolation structure located between the first and second photoelectric conversion elements and recessed from the second surface into the semiconductor substrate, and configured to extend along a first direction;
a second pixel isolation structure located between the first and third photoelectric conversion elements and recessed from the second surface into the semiconductor substrate, and configured to extend along a second direction perpendicular to the first direction; and
a body bias region disposed in an intersection region where an extension line of the first pixel isolation structure in the first direction and an extension line of the second pixel isolation structure in the second direction cross each other, the body bias region configured to receive a bias voltage.

14. The image sensing device according to claim 13, further comprising:
a shared floating diffusion region supported by the semiconductor substrate, and configured to be coupled to receive and store photocharges generated by each of the first to fourth photoelectric conversion elements; and
a first shared source follower transistor supported by the semiconductor substrate and including a gate structured to overlap the first photoelectric conversion element and configured to receive a voltage corresponding to the photocharges stored in the shared floating diffusion region.

15. The image sensing device according to claim 14, further comprising:
a second shared source follower transistor supported by the semiconductor substrate and including a gate structured to overlap the second photoelectric conversion element and configured to receive a voltage corresponding to the photocharges stored in the shared floating diffusion region.

16. The image sensing device according to claim 15, wherein:
the first pixel isolation structure extends in the first direction so as to overlap a space between the first shared source follower transistor and the second shared source follower transistor.

17. The image sensing device according to claim 15, further comprising:
a shared reset transistor configured to reset the shared floating diffusion region; and
a shared selection transistor configured to output a pixel signal using electrical signals output from the first and second shared source follower transistors,
wherein
a gate of the shared reset transistor is configured to overlap the third photoelectric conversion element; and
a gate of the shared selection transistor is configured to overlap the fourth photoelectric conversion element.

18. The image sensing device according to claim 17, wherein:
each of the gate of the first shared source follower transistor and the gate of the shared reset transistor includes an oxide layer,
wherein
the oxide layer of the gate of the first shared source follower transistor is thinner than the oxide layer of the gate of the shared reset transistor.

19. The image sensing device according to claim 17, wherein:
each of the gate of the first shared source follower transistor and the gate of the shared selection transistor includes an oxide layer,
wherein
the oxide layer of the gate of the first shared source follower transistor is thinner than the oxide layer of the gate of the shared selection transistor.

20. The image sensing device according to claim 13, wherein:
the semiconductor substrate has a first conductivity type, each of the first to fourth photoelectric conversion elements has a second conductivity type, and the body bias region has the first conductivity type,
wherein
a doping concentration of the first conductivity type in the body bias region is higher than a doping concentration of the first conductivity type in the semiconductor substrate.

21. An image sensing device comprising:
first to fourth pixels arranged in a (2×2) matrix structure, each of the first to fourth pixels including a photoelectric conversion element configured to generate photocharges in response to incident light;
a body bias region disposed at a center of the (2×2) matrix structure and configured to receive a bias voltage as an input of the first to fourth pixels;
a shared source follower transistor including a gate configured to overlap the first pixel and the second pixel, the gate of the shared source follower transistor disposed to be spaced apart from the body bias region, and configured to receive a voltage corresponding to a shared floating diffusion region storing the photocharges; and
a first pixel isolation structure disposed between the first pixel and the second pixel and configured to extend in a first direction, and spaced apart in the first direction from the body bias region and the gate of the shared source follower transistor.

22. The image sensing device according to claim 21, further comprising:
a second pixel isolation structure disposed between the first pixel and the third pixel and configured to extend in a second direction perpendicular to the first direction and spaced apart from the body bias region in the second direction; and
a shared reset transistor including a gate configured to overlap the third pixel and spaced apart from the body bias region, and wherein the gate of the shared reset transistor is configured to reset the shared floating diffusion region.

23. The image sensing device according to claim 22, wherein:
each of the gate of the shared source follower transistor and the gate of the shared reset transistor includes an oxide layer,
wherein
the oxide layer of the gate of the shared source follower transistor is thinner than the oxide layer of the gate of the shared reset transistor.
